(19) United States
(12) Patent Application Publication
(10) Pub. No.: US 2011/0310557 A1
(43) Pub. Date: Dec. 22, 2011

(54) Display Apparatus and Electronic Apparatus

(76) Inventor: Toshio Ooe, Akishima-shi (JP)

(21) Appl. No.: 13/152,940

(22) Filed: Jun. 3, 2011

(30) Foreign Application Priority Data
Jun. 18, 2010 (JP) 2010-139491

(51) Int. Cl. H05K 7/20

(52) U.S. Cl. 361/692; 361/697

(57) ABSTRACT

According to one embodiment, a display apparatus is provided. The display apparatus includes: a display panel; a case including a cover portion provided with an air outlet and a first air inlet; a mask portion provided with an opening which is connected to the cover portion via the display panel and through which the display panel is exposed, a slant portion which extends to the cover portion, and a second air inlet located at the slant portion. The apparatus further includes: a support stand which supports the case; a circuit board housed in the case and mounted with a heat generation body; a heat sink housed in the case and configured to face the air outlet; a heat pipe which thermally connects the heat generation body and the heat sink; and a fan including an air discharge outlet which is directed to the heat sink.

### CROSS REFERENCE TO RELATED APPLICATION(S)

The application is based upon and claims the benefit of priority from Japanese Patent Application No. 2010-139491 filed on Jun. 18, 2010; the entire content of which are incorporated herein by reference.

### FIELD

Embodiments described herein relate generally to a display apparatus and an electronic apparatus having a cooling fan.

### BACKGROUND

Display apparatus and electronic apparatus may be equipped with a cooling fan.

Recent display apparatus and electronic apparatus are required to be increased further in cooling efficiency.

### BRIEF DESCRIPTION OF THE DRAWINGS

FIG. 1 is a perspective view showing an electronic apparatus according to a first embodiment.

FIG. 2 is a bottom view showing a bottom wall of the electronic apparatus of FIG. 1.

FIG. 3 is a perspective view showing parts of the bottom wall and a circumferential wall of the electronic apparatus of FIG. 1.

FIG. 4 is a bottom view showing the inside of the electronic apparatus of FIG. 1.

FIG. 5 is a perspective view showing an inside of part of the electronic apparatus of FIG. 1.

FIG. 6 is a bottom view showing the inside of part of the electronic apparatus of FIG. 1 with several sealing members removed.

FIG. 7 is a plan view showing wiring patterns of a circuit board shown in FIG. 6.

FIG. 8 is a bottom view showing the inside of part of the electronic apparatus of FIG. 1.

FIG. 9 is a sectional view showing the electronic apparatus taken along line IX-IX in FIG. 8.

FIG. 10 is a sectional view showing the electronic apparatus taken along line X-X in FIG. 8.

FIG. 11 is a sectional view showing the electronic apparatus taken along line XI-XI in FIG. 8.

FIG. 12 is a schematic sectional view showing the inside of the electronic apparatus shown in FIG. 8.

FIG. 13 is a schematic sectional view showing the electronic apparatus taken along line XIII-XIII in FIG. 12.

FIG. 14 is a schematic sectional view showing a duct structure of the electronic apparatus shown in FIG. 8.

FIG. 15 is a sectional view showing an electronic apparatus according to a second embodiment.

FIG. 16 is a perspective view showing a display device according to a third embodiment.

FIG. 17 is a side view showing the display device according to the third embodiment.

FIG. 18 is a rear view showing the display device according to the third embodiment.

### DETAILED DESCRIPTION

In general, according to one exemplary embodiment, a display apparatus is provided. The display apparatus includes: a display panel; a case including a cover portion provided with an air outlet and a first air inlet; a mask portion provided with an opening which is connected to the cover portion via the display panel and through which the display panel is exposed, a slant portion which extends to the cover portion, and a second air inlet located at the slant portion. The apparatus further includes: a support stand which supports the case; a circuit board housed in the case and mounted with a heat generation body; a heat sink housed in the case and configured to face the air outlet; a heat pipe which thermally connects the heat generation body and the heat sink; and a fan including an air discharge outlet which is directed to the heat sink.

Electronic apparatus and a display apparatus according to several embodiments will be hereinafter described with reference to the drawings.

### First Embodiment

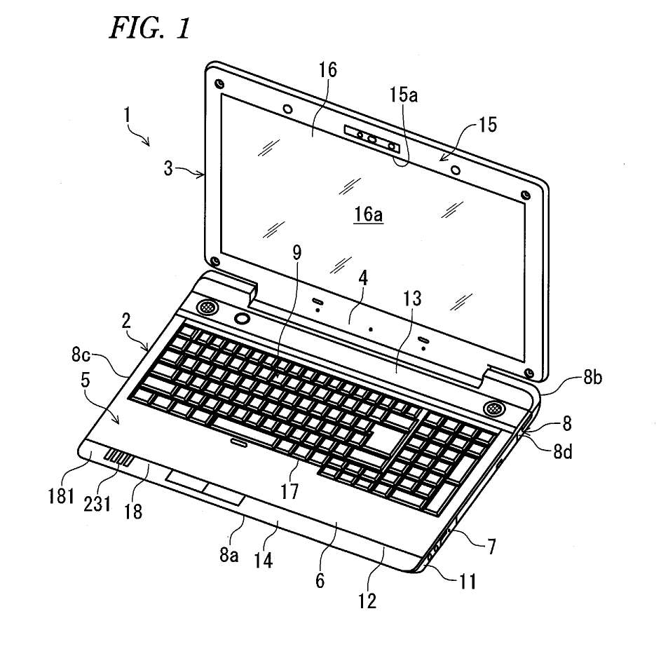

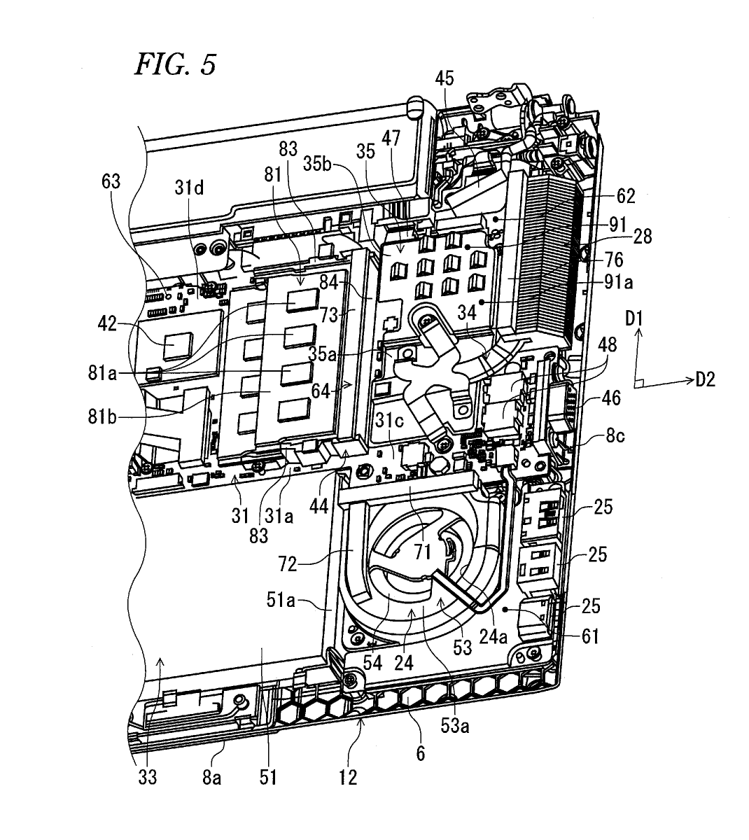

FIGS. 1-14 show an electronic apparatus (notebook personal computer (PC)) 1 according to a first embodiment. Electronic apparatus to which the invention can be applied are not limited to notebook PCs, and the embodiment can also be applied to a wide variety of electronic apparatus other than notebook PCs, such as display apparatus (e.g., TV receivers), recording/reproducing apparatus, personal digital assistants (PDAs), and game machines.

As shown in FIG. 1, the electronic apparatus 1 is equipped with a main unit 2, a display unit 3, and a hinge 4. The main unit 2 is an electronic apparatus main body which incorporates a main board. The main unit 2 has a case 5. The case 5 has a top wall 6, a bottom wall 7, and a circumferential wall 8 and has a flat box shape.

When the electronic apparatus 1 is placed on a desk, the bottom wall 7 faces the top surface of the desk so as to be approximately parallel with the top surface. The top wall 6 extends approximately parallel with the bottom wall 7 with a space interposed in between. A keyboard 9 is attached to the top wall 6. The circumferential wall 8 is erected from the bottom wall 7 and connects the peripheries of the bottom wall 7 and the top wall 6.

The case 5 has a base 11 and a cover 12. The base 11 includes the bottom wall 7 and part of the circumferential wall 8. The cover 12 includes the top wall 6 and part of the circumferential wall 8. The case 5 is formed by combining the cover 12 with the base 11.

The case 5 has a rear end portion 13 (first end portion) to which the display unit 3 is connected rotatably and a front end portion 14 (second end portion) which is opposite to the rear end portion 13. The circumferential wall 8 has a front wall 8a, a read wall 8b, a left side wall 8c, and a right side wall 8d. The front wall 8a, which is part of the front end portion 14, extends in the width direction (right-left direction) of the case 5. The rear wall 8b, which is part of the rear end portion 13, also extends in the width direction of the case 5. The left side wall 8c and the right side wall 8d extend in the depth direction (front-rear direction) of the case 5 and connect the ends of the front wall 8a and the rear wall 8b.

The display unit 3 is connected to the rear end portion 13 of the main unit 2 rotatably (so as to be closable and openable) by means of the hinge 4. The display unit 3 can be rotated between a closed portion where it is put down so as to cover the main unit 2 from above and an open position where it is erected from the main unit 2.

As shown in FIG. 1, the display unit 3 is equipped with a display case 15 and a display panel 16 which is housed in the display case 15. A display screen 16a of the display panel 16 can be exposed through an opening 15a which is formed in the front wall of the display case 15.

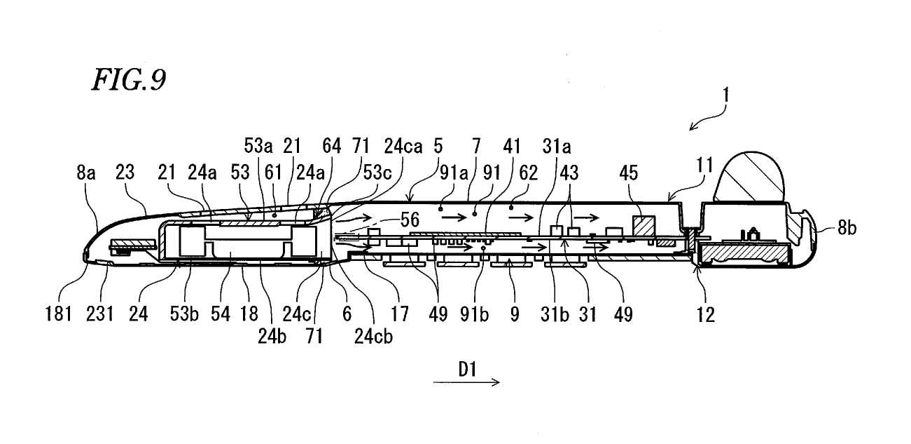

As shown in FIG. 1, the top wall 6 has a keyboard mounting portion 17 to which the keyboard 9 is attached, a palm rest 18, and a slant portion 181 which is continuous with the palm rest 18. The palm rest 18 is located on the user's side of the keyboard mounting portion 17, that is, between the keyboard mounting portion 17 and the front wall 8a. As shown in FIG. 9, the keyboard mounting portion 17 is recessed toward the inside of the case 5 with respect to the palm rest 18, whereby the top surface of the keyboard 9 which is attached to the keyboard mounting portion 17 is approximately flush with or a little higher than the top surface of the palm rest 18.

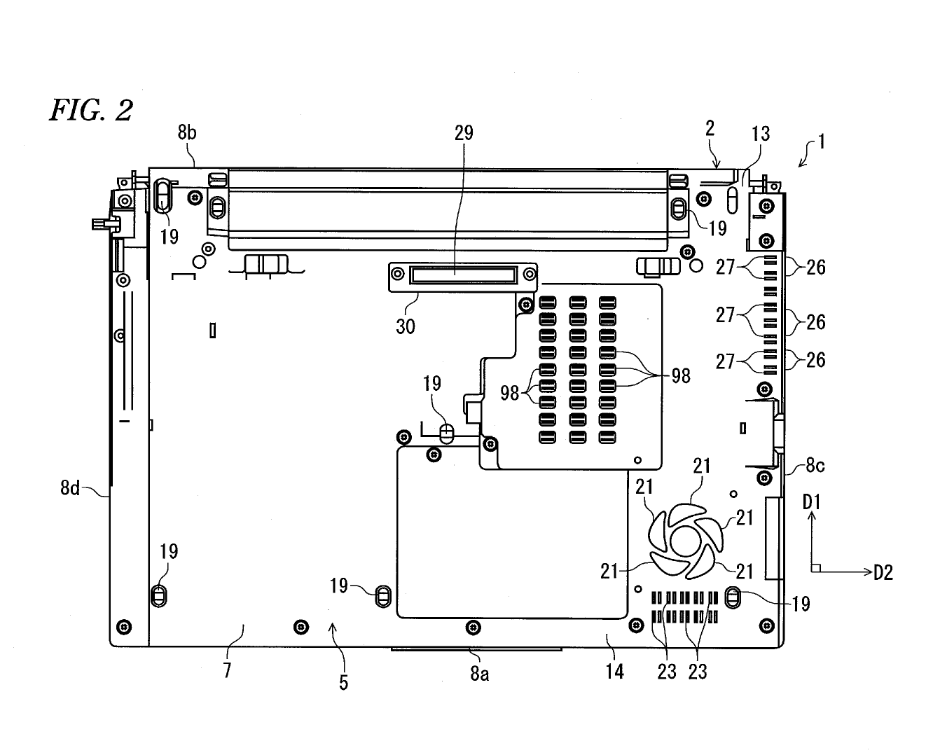

As shown in FIG. 2, the bottom wall 7 of the case 5 is provided with plural legs 19. The legs 19 come into contact with a desk surface, whereby the bottom wall 7 of the case 5 is supported so as to be spaced from the desk surface. As shown in FIGS. 1 to 3, the case 5 is formed with first air inlets 21, second air inlets 22, third air inlets 23, and fourth air inlets 231. A set of first air inlets 21, a set of second air inlets 22, a set of third air inlets 23, and a set of fourth air inlets 231 are spaced from each other and concentrated in a front-left portion of the case 5.

As shown in FIG. 1, the fourth air inlets 231 are formed in the slant portion 181. As shown in FIG. 2, the first air inlets 21 and the third air inlets 23 are formed in the bottom wall 7. The first air inlets 21 are located under and opposed to a cooling fan 24 (described later). The third air inlets 23 are not located under the cooling fan 24 and are formed between the first air inlets 21 and the front wall 8a.

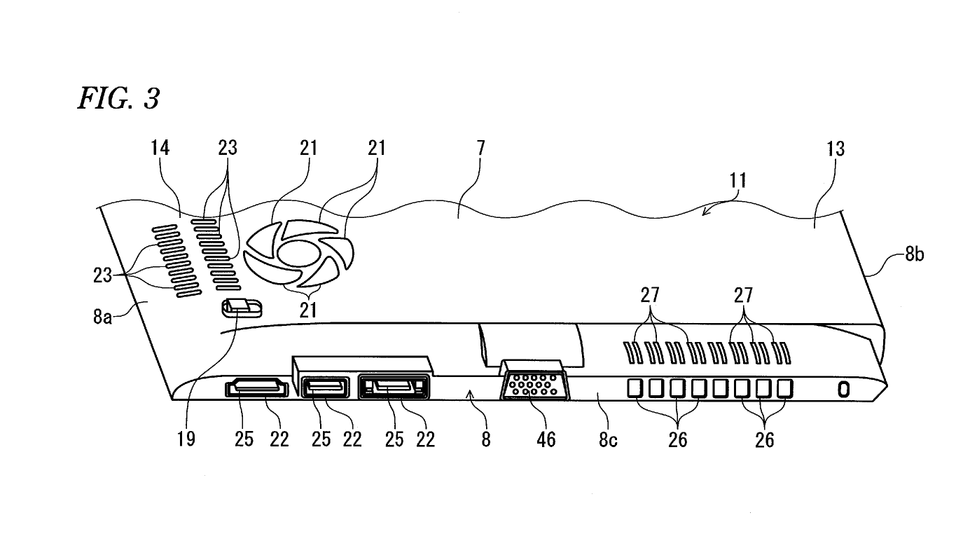

As shown in FIG. 3, the second air inlets 22 are openings which are formed through the left side wall 8c to expose various connectors 25. The second air inlets 22 cause external air to flow into the case 5 through the gaps formed between the connectors 25 and the left side wall 8c.

As shown in FIG. 3, the case 5 is formed with first air outlets 26 and second air outlets 27. The first air outlets 26 are formed in a portion, belonging to the rear end portion 13a, of the left side wall 8c of the case 5 in such a manner that part of them are located beside the keyboard 9 and the other part are located in the rear of the former part. The first air outlets 26 are opposed to a heat sink 28 (described later) from one side. The second air outlets 27 are formed in a portion, belonging to the rear end portion 13a, of the bottom wall 7 of the case 5 and are opposed to the heat sink 28 from below. As shown in FIG. 2, the bottom wall 7 is formed with an opening 30 which exposes a docking connector 29 to the outside.

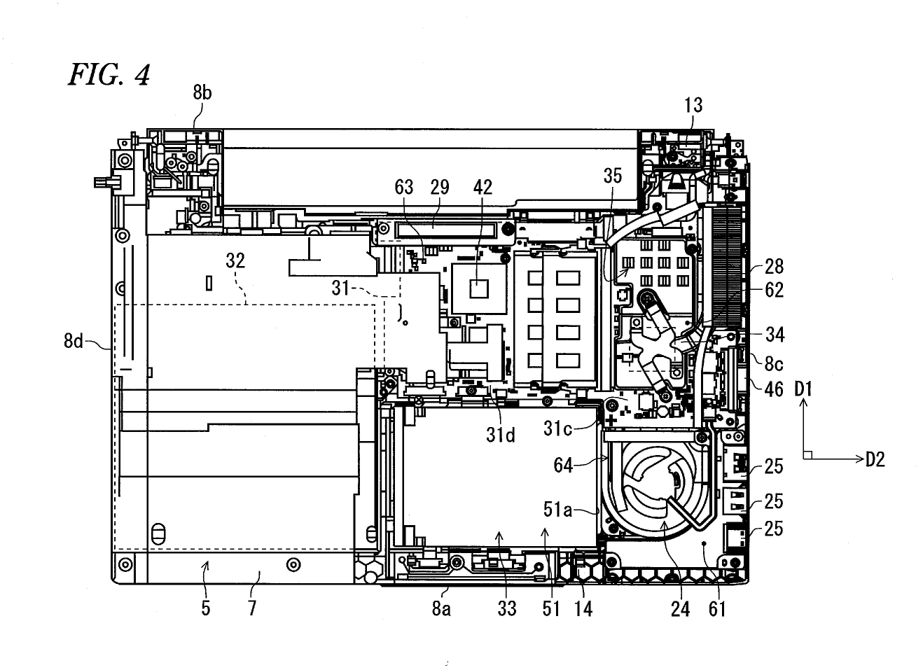

As shown in FIG. 4, the case 5 houses a circuit board 31, an optical disc drive (ODD) 32, a storage device 33, the heat sink 28, a heat pipe 34, a radiator plate 35, and the cooling fan 24. The circuit board 31 is a main board, for example.

The circuit board 31 has a first surface (bottom surface) 31a and a second surface (top surface) 31b which is opposite to the first surface 31a. Alternatively, the first surface 31a and the second surface 31b may be a top surface and a bottom surface, respectively.

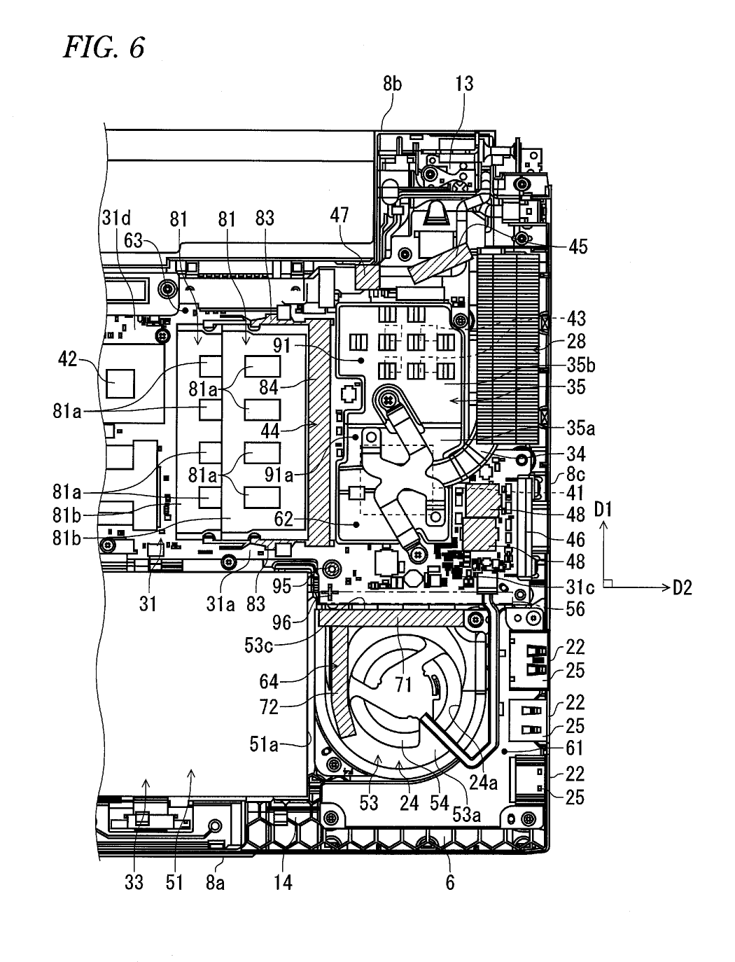

As shown in FIG. 6, the first surface 41a of the circuit board 31 is mounted with a central processing unit (CPU) 41, a platform controller hub (PCH) 42, power circuit components 43, a memory slot connector 44, an LCD connector 45, an I/O connector 46, a first power coil 47, and second power coils 48.

The CPU 41 (example first heat generation body) is a component that generates most heat among the components mounted on the circuit board 31. The PCH 42 (example second heat generation body) is a component that works well with natural heat radiation, for example. The power circuit components 43 (example third heat generation bodies) are components that generate relatively large amounts of heat among the components mounted on the circuit board 31.

As shown in FIG. 9, the second surface 31b of the circuit board 31 is mounted with power circuit components 49 (example heat generation bodies). Heat generation bodies mounted on the circuit board 31 are not limited to the above ones.

As shown in FIG. 4, the direction from the front end portion 14 of the case 5 to its rear end portion 13 is defined as a first direction D1. And the direction that is approximately perpendicular to the first direction D1 and is directed from the right side wall 8d to the left side wall 8c is defined as a second direction D2. An air discharge outlet 24c of the cooling fan 24 (described later) is opened in the first direction D1.

In this specification, the top, bottom, right, and left are defined in the state that the electronic apparatus 1, for example, has a normal posture (see FIG. 1). Therefore, in descriptions that were or will be made with reference to drawings (e.g., FIGS. 2, 4 to 6, and 8 to 11) in which the electronic apparatus 1, for example, is drawn upside down, the top, bottom, right, and left are opposite to those as viewed in those drawings.

As shown in FIG. 9, the circuit board 31 occupies a lower portion of the keyboard mounting portion 17. As shown in FIG. 4, the circuit board 31 has a first portion 31c which is located between the cooling fan 24 and the heat sink 28 and a second portion 31d which is not located between the cooling fan 24 and the heat sink 28.

The first portion 31c is opposed to the air discharge outlet 24c of the cooling fan 24 in the first direction D1. That is, the first portion 31c is directly exposed to a cool wind that is discharged from the cooling fan 24. And the first portion 31c is opposed to the heat sink 28 in the second direction D2. On the other hand, the second portion 31d is not opposed to the air discharge outlet 24c of the cooling fan 24 in the first direction D1.

The CPU 41 and the power circuit components 43 are mounted on the first portion 31c of the circuit board 31 and hence are located between the heat sink 28 and the cooling fan 24. The PCH 42 is mounted on the second portion 31d of the circuit board 31 and hence is not located between the heat sink 28 and the cooling fan 24.

The heat sink 28 (example heat radiation member) is, for example, a fin unit having plural fins. The heat sink 28 is provided in the rear end portion 13 of the case 5 and faces the first air outlets 26 of the case 5. The heat sink 28 occupies a lower portion of the keyboard mounting portion 17. The gaps between the fins of the heat sink 28 face the first air outlets 26.

As shown in FIG. 6, the CPU 41 is located closer to the cooling fan 24 than the power circuit components 43 are. Extending from the CPU 41 to the heat sink 28, the heat pipe 34 (example heat transport member) thermally connects the CPU 41 to the heat sink 28 and moves heat from the CPU 41 to the heat sink 28.

The radiator plate 35 is a sheet metal member, for example, and has a first portion 35a which faces the CPU 41 and a second portion 35b which is not face the CPU 41. The first portion 35a is thermally connected to the CPU 41. The second portion 35b is different in height from the first portion 35a and extends from the first portion 35a rearward (i.e., in the air discharge direction of the cooling fan 24). The second portion 35b covers the power circuit components 43 from below with a gap formed in between. For example, the radiator plate 35 is not thermally connected to the power circuit components 43.

As shown in FIG. 4, the ODD 32 occupies a right portion of the case 5 and hence is located on the side opposite to the circuit board 31. The storage device 33, an example of which is a hard disk drive (HDD), is disposed in the front end portion 14 of the case 5 adjacent to the cooling fan 24. The storage device 33 has a case 51 and magnetic disks (not shown) housed in the case 51. A side surface 51a of the case 51 extends in a plane-like manner and faces the cooling fan 24 from one side. The side surface 51a of the case 51 serves as a vertical wall surface which faces the cooling fan 24 on the side opposite to the left side wall 8c of the case 5.

As shown in FIG. 6, the cooling fan 24 is spaced from the heat sink 28 and disposed in a left portion of the front end portion 14 of the case 5. As shown in FIG. 9, the cooling fan 24 is disposed under the palm rest 18. That is, the palm rest 18 is not disposed under the keyboard mounting portion 17 (this space of the case 5 is relatively thin) but under the palm rest 18 (this space of the case 5 is relatively thick). As shown in FIG. 9, gaps are formed between the cooling fan 24 and the bottom wall 7 of the case 5 and between the cooling fan 24 and the top wall 6 of the case 5.

The cooling fan 24 is a centrifugal fan and has a fan case 53 and impeller 54. The fan case 53 is formed with first air suction inlets 24a, a second air suction inlet 24b, and the air discharge outlet 24c.

As shown in FIG. 9, the fan case 53 has a bottom wall 53a which faces the bottom wall 7, a top wall 53b which is opposite to the bottom surface 53a and faces the top wall 6, and a circumferential wall 53c which faces the circuit board 31. The first air suction inlets 24a are formed in the bottom wall 53a of the fan case 53 and face the first air inlets 21 of the bottom wall 7. The second air suction inlet 24b is formed in the top wall 53b of the fan case 53 and hence is opposite to the first air suction inlets 24a. The second air suction inlet 24b faces the palm rest 18 with a gap formed in between.

As shown in FIG. 9 and as described above, the air discharge outlet 24c is opened in the first direction D1 and hence is directed to the CPU 41 which is mounted on the circuit board 31. The height of the air discharge outlet 24c is greater than the thickness of the circuit board 31. The front edge of the circuit board 31 faces an approximately central portion, in the vertical direction, of the air discharge outlet 24c. The term “faces an approximately central portion of the air discharge outlet 24c” means “does not face the top end portion or the bottom end portion of the air discharge outlet 24c.” The front edge of the circuit board 31 is not necessarily required to face the central portion, in the vertical direction, of the air discharge outlet 24c.

That is, the air discharge outlet 24c faces spaces that are located over and under the circuit board 31. The air discharge outlet 24c has a first portion 24ca which is located on the side of the first surface 31 a of the circuit board 31 and a second portion 24cb which is located on the side of the second surface 31b of the circuit board 31.

The cooling fan 24 sucks air existing in the case 5 through the first air suction inlets 24a and the second air suction inlet 24b and discharges the sucked air through the air discharge outlet 24c. In doing so, the cooling fan 24 discharges the sucked air to the spaces that are located over and under the circuit board 31.

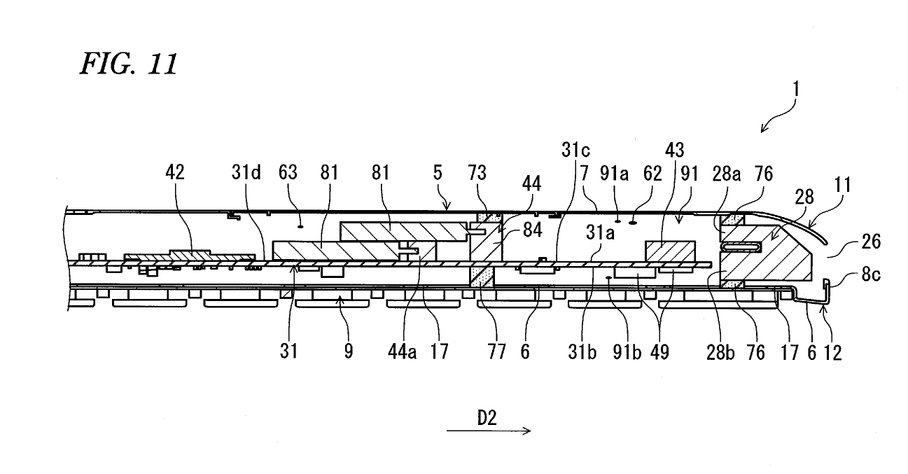

On the other hand, as shown in FIG. 11, the heat sink 28 is thicker than the circuit board 31. The left edge of the circuit board 31 faces an approximately central portion, in the thickness direction, of the heat sink 28. The term “faces an approximately central portion of the heat sink 28” means “does not face the top end portion or the bottom end portion of the heat sink 28.” The left edge of the circuit board 31 is not necessarily required to face the central portion, in the vertical direction, of the air discharge outlet 24c.

That is, the heat sink 28 is exposed to the spaces that are located over and under the circuit board 31. The heat sink 28 has a first portion 28a which is located on the side of the first surface 31a of the circuit board 31 and a second portion 28b which is located on the side of the second surface 31b of the circuit board 31. The first portion 28a is exposed to air that has flown to the space on the side of the first surface 31a, and the second portion 28b is exposed to air that has flown to the space on the side of the second surface 31b.

As shown in FIGS. 6 and 9, an end portion of the circuit board 31 that faces the air discharge outlet 24c of the cooling fan 24 has a non-component-mounted area 56, which is 5 mm, for example, in width and extends along the front edge of the circuit board 31 in the width direction of the air discharge outlet 24c. The non-component-mounted area 56 is a margin which is placed on a rail of a mounting apparatus in a process of mounting components on a bare circuit board, such as a reflow process. Mounted with no components, the non-component-mounted area 56 does not tend to obstruct the flow of air that is discharged from the cooling fan 24.

As shown in FIG. 4, the electronic apparatus 1 is equipped with wind shields 64 which separate a first room (first region) 61, a second room (second region) 62, a third room (third region) 63 in the case 5. The first room 61 is an air suction room which allows the cooling fan 24 to suck fresh air. The second room 62 is a room in which components that generate relatively large amounts of heat are mounted in a concentrated manner and through which a cooling wind flows from the cooling fan 24 toward the heat sink 28. The third room 63 houses components for which natural heat radiation, for example, is enough. The term “room” means a region (or portion) in the case 5. A room is not necessarily required to be isolated completely from other rooms (regions).

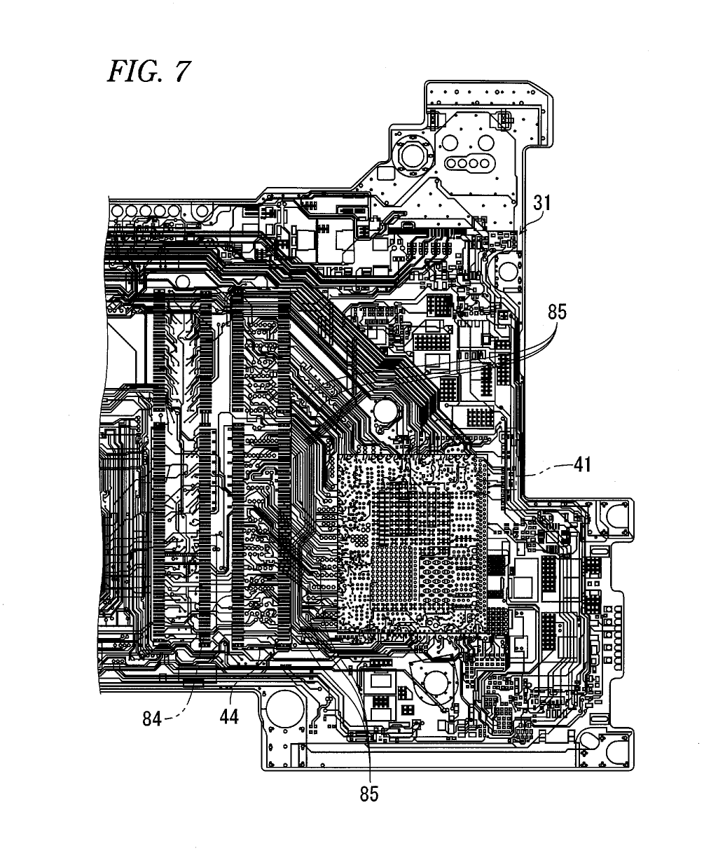

As shown in FIGS. 6 and 7, in the embodiment, the memory slot connector 44, the LCD connector 45, the first power coil 47, the second power coil 48, and several sealing members 71 to 77 which are mounted on the circuit board 31 cooperate to constitute the wind shields 64.

The several sealing members 71 to 77 (example elastic members, example non-conductive members) are insulators made of such a material as sponge or rubber. FIG. 6 shows a state that the sealing members 73 to 75 are removed. For convenience of description, the components that constitute the wind shields 64 are hatched in FIGS. 6 and 7.

A wind shield structure of the first room 61 will be described first.

As shown in FIG. 6, a first sealing member 71 and a second sealing member 72 are attached to the bottom wall 53a of the cooling fan 24. The first sealing member 71 extends in the width direction of the air discharge outlet 24c of the cooling fan 24 (i.e., in the second direction D2) parallel with the air discharge outlet 24c. That is, the first sealing member 71 is disposed between the first air suction inlets 24a and the air discharge outlet 24c and partitions a space inside the case 5.

The second sealing member 72 extends in the first direction D1 parallel with the right end portion of the cooling fan 24. The second sealing member 72 is disposed on the other side of the first air suction inlets 24a of the cooling fan 24 from the left side wall 8c of the case 5. That is, the first air suction inlets 24a of the cooling fan 24 are located between the second sealing member 72 and the left side wall 8c.

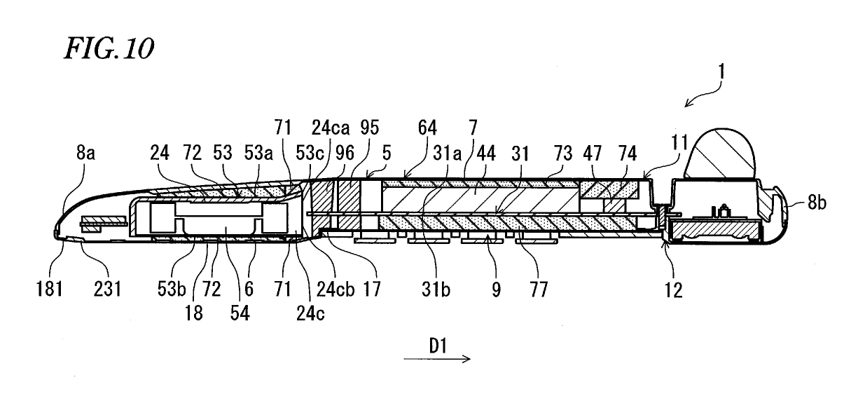

As shown in FIGS. 9 and 10, the first sealing member 71 and the second sealing member 72 are disposed between the bottom wall 53a of the cooling fan 24 and the bottom wall 7 of the case 5. The first sealing member 71 and the second sealing member 72 are compressed by the bottom wall 53a of the cooling fan 24 and the inner surface of the bottom wall 7 of the case 5 and thereby seal the space between them airtight.

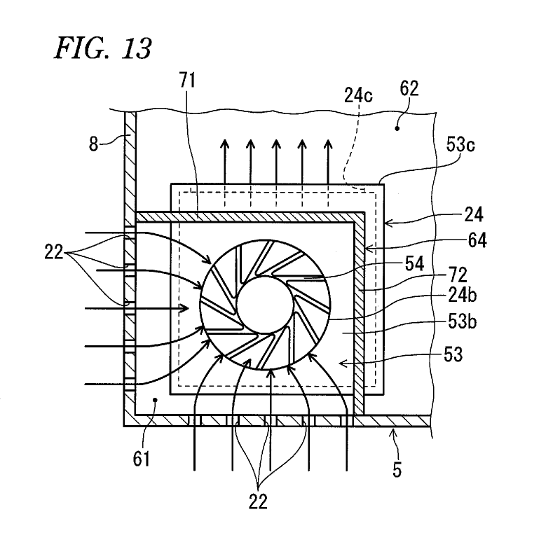

As a result, as schematically shown in FIG. 13, the first room 61 which is enclosed by the first sealing member 71, the second sealing member 72, the left side wall 8c of the case 5, and the front wall 8a of the case 5 is formed in a corner portion of the case 5. That is, the first sealing member 71 and the second sealing member 72 partition a space inside the case 5 into the first room 61 and the second room 62.

In the embodiment, the first sealing member 71 and the second sealing member 72 are provided only on the surfaces of the cooling fan 24. That is, the first sealing member 71 and the second sealing member 72 do not separate the first room 61 completely but partially.

Alternatively, the first sealing member 71 and the second sealing member 72 may extend to regions that are outside the cooling fan 24 to separate the first room 61 completely in the case 5. In the embodiment, the side surface 51a of the case 51 of the storage device 33 serves as an auxiliary wall surface of the first room 61.

As shown in FIGS. 9 and 10, the first sealing member 71 and the second sealing member 72 are disposed on the top wall 53b of the cooling fan 24 as on the bottom surface 53a. That is, the first sealing member 71 extends in the width direction of the air discharge outlet 24c of the cooling fan 24 parallel with the air discharge outlet 24c. The first sealing member 71 is disposed between the second air suction inlet 24b and the air discharge outlet 24c and partitions a space inside the case 5. The second sealing member 72 extends in the first direction D1 parallel with the right end portion of the cooling fan 24.

The first sealing member 71 and the second sealing member 72 are disposed between the top wall 53b of the cooling fan 24 and the inner surface of the top wall 6 (palm rest 18) of the case 5. The first sealing member 71 and the second sealing member 72 are compressed by the top wall 53b of the cooling fan 24 and the inner surface of the top wall 6 of the case 5 and thereby seal the space between them airtight.

As shown in FIGS. 6 and 9, the first air inlets 21, the second air inlets 22, and the third air inlets 23 of the case 5, and the first air suction inlets 24a and the second air suction inlet 24b of the cooling fan 24 communicate with the first room 61. The first room 61 has no heat generation body mounted on the circuit board 31. The first room 61 communicates with the outside of the case 5 via the first air inlets 21, the second air inlets 22, and the third air inlets 23 and hence fresh air can flow into the first room 61. Therefore, the first room 61 is lower in air temperature than the other rooms.

Next, a wind shield structure of the second room (duct portion) 62 will be described.

As shown in FIG. 6, the memory slot connector 44 to which a memory 81 is attached is mounted on the circuit board 31. The memory slot connector 44 is an example board component, an example long connector, and an example component housed in a case. The term “long connector” means a connector whose longitudinal length is greater than the length of each sideline of the chip of the CPU 41 (example first heat generation body). The long connector is not limited to the memory slot connector 44 and may be a docking connector, a TV tuner connector, or the like.

As shown in FIG. 6, the longitudinal direction of the memory slot connector 44 is parallel with the air discharge direction of the cooling fan 24 (coincides with the first direction D1). The memory 81 has a memory board 81b which is mounted with plural memory chips 81a. The memory slot connector 44 is disposed adjacent to the CPU 41 with the memory 81 located on its side opposite to the CPU 41.

The memory slot connector 44 includes a pair of holding portions 83 for holding the memory 81 in such a manner that the memory 81 is spaced from the circuit board 31 and a terminal portion 84 which is fixed to the circuit board 31. The terminal portion 84 has a slot to which the memory 81 is connected electrically and plural interconnections for connecting the memory 81 to the CPU 41. The terminal portion 84 is in close contact with the circuit board 31, that is, no gap is formed between the terminal portion 84 and the circuit board 31.

As shown in FIG. 11, the memory slot connector 44 is a second-stage connector of what is called a two-stage memory attachment portion. That is, another memory slot connector 44a exists between the memory 81 which is attached to the memory slot connector 44 and the circuit board 31. The terminal portion 84 of the memory slot connector 44 is thus relatively large in height.

As shown in FIG. 6, in the memory slot connector 44, the terminal portion 84 is closer to the CPU 41 than the holding portions 83 are. Part of the memory slot connector 44 is opposed to the CPU 41. The memory slot connector 44 is disposed parallel with the CPU 41. As shown in FIG. 7, the terminal portions 84 are electrically connected to the CPU 41 by plural wiring patterns 85.

As shown in FIG. 6, the memory slot connector 44 is located beside the CPU 41 and the power circuit components 43. The memory slot connector 44 are opposed to part of the heat sink 28, the second power coil 48, and the I/O connector 46 in the second direction D2.

As shown in FIG. 6, the first power coil 47 and the LCD connector 45 (example board components) are disposed between the rear end of the memory slot connector 44 and the rear end of the heat sink 28. The first power coil 47 and the LCD connector 45 are arranged in the second direction D2.

The first power coil 47 and the LCD connector 45 are opposed to the air discharge outlet 24c of the cooling fan 24 in the first direction D1. That is, air that is discharged from the air discharge outlet 24c of the cooling fan 24 passes the CPU 41 and the power circuit components 43 and then hits the first power coil 47 and the LCD connector 45, whereby the air is deflected toward the heat sink 28.

On the other hand, the second power coil 48 is located on the opposite side of the CPU 41 to the memory slot connector 44. The interval between the second power coil 48 and the memory slot connector 44 is approximately equal to the width of the air discharge outlet 24c of the cooling fan 24.

The thus-arranged memory slot connector 44, first power coil 47, LCD connector 45, and second power coil 48 cooperate with the bottom wall 7 and the left side wall 8c of the case 5 to form a wind guide passage 91 having a duct structure through which a cool wind flows from the cooling fan 24 toward the heat sink 28. That is, each of the memory slot connector 44, the first power coil 47, the LCD connector 45, and the second power coil 48 serves as partial walls of the wind guide passage 91.

More specifically, the wind guide passage 91 of the embodiment has a first flow passage 91a and a second flow passage 91b. The first flow passage 91a is formed at the first surface 31a side of the circuit board 31 (i.e., between the circuit board 31 and the bottom wall 7 of the case 5) and is generally L-shaped. The second flow passage 91b is formed at the second surface 31b side of the circuit board 31 (i.e., between the circuit board 31 and the top wall 6 of the case 5) and is generally L-shaped in the same manner as the first flow passage 91a is.

The memory slot connector 44, the first power coil 47, the LCD connector 45, and the second power coil 48 form the first flow passage 91a. As shown in FIG. 6, the CPU 41, the power circuit components 43, the heat pipe 34, and the radiator plate 35 are located in the first flow passage 91a.

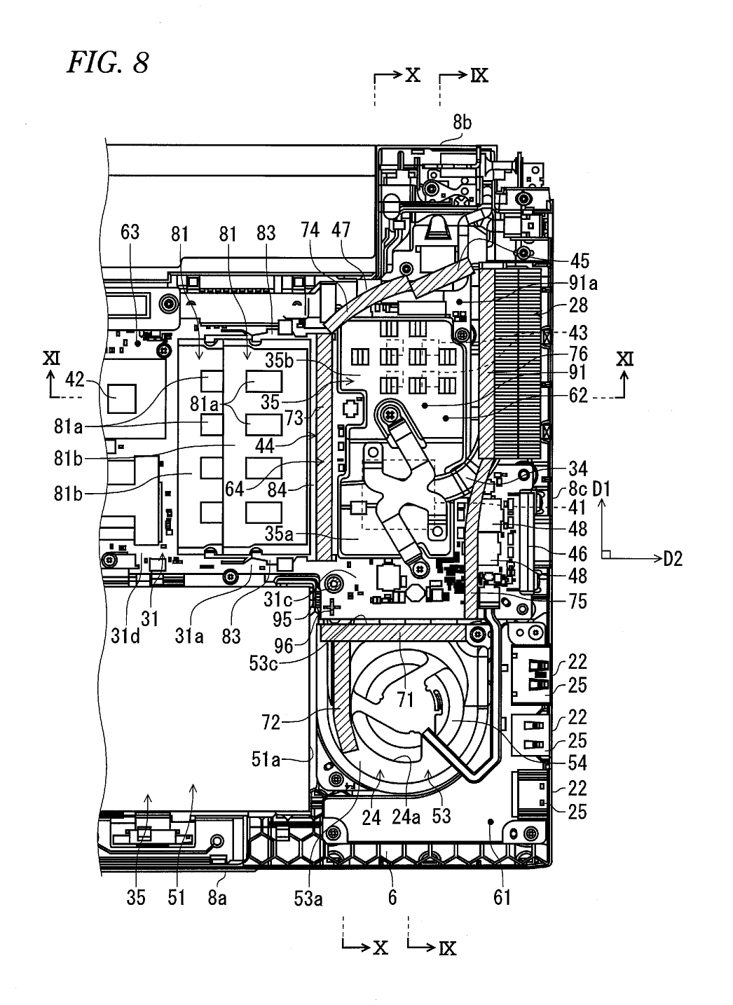

As shown in FIGS. 8 and 10, a third sealing member 73 is disposed between the terminal portion 84 of the memory slot connector 44 and the inner surface of the bottom wall 7 of the case 5. The third sealing member 73 extends in the first direction D1 and is approximately the same in length as the terminal portion 84 of the memory slot connector 44.

The third sealing member 73 is compressed by the memory slot connector 44 and the bottom wall 7 of the case 5 and thereby seals the space between them airtight. The third sealing member 73 serves as a partial wall of the first flow passage 91a of the wind guide passage 91.

As shown in FIGS. 8 and 10, the case 5 has a boss 95 and a rib 96 as projections which project from the inner surface of the bottom wall 7 of the case 5 to the circuit board 31. The boss 95 and the rib 96 are located between the cooling fan 24 and the memory slot connector 44 and serve as partial walls of the wind guide passage 91.

As shown in FIG. 8, a fourth sealing member 74 is disposed between the first power coil 47 and the inner surface of the bottom wall 7 of the case 5. The fourth sealing member 74 extends from the rear end of the memory slot connector 44 to the front end of the LCD connector 45. The fourth sealing member 74 is compressed by the first power coil 47 and the inner surface of the bottom wall 7 of the case 5 and thereby seals the space between them airtight. The fourth sealing member 74 may extend to the rear end of the heat sink 28. The fourth sealing member 74 may be disposed between the LCD connector 45 and the inner surface of the bottom wall 7 of the case 5.

As shown in FIG. 8, a fifth sealing member 75 is disposed between the second power coil 48 and the inner surface of the bottom wall 7 of the case 5. The fifth sealing member 75 extends from the rear end of the cooling fan 24 to the front end of the heat sink 28. The fifth sealing member 75 is compressed by the second power coil 48 and the inner surface of the bottom wall 7 of the case 5 and thereby seals the space between them airtight. The fifth sealing member 75 may be provided so as to extend along part of the path between the rear end of the cooling fan 24 and the front end of the heat sink 28. Each of the fourth sealing member 74 and the fifth sealing member 75 serves as a partial wall of the first flow passage 91a of the wind guide passage 91.

As shown in FIGS. 8 and 11, a sixth sealing member 76 is disposed between the heat sink 28 and the inner surface of the bottom wall 7 of the case 5. The sixth sealing member 76 extends alongside the entire heat sink 28 in its longitudinal direction (first direction D1). The sixth sealing member 76 is compressed by the heat sink 28 and the inner surface of the bottom wall 7 of the case 5 and thereby seals the space between them airtight. As a result, a cool wind that has reached the heat sink 28 is discharged to the outside after passing between the fins of the heat sink 28 without passing through the space between the heat sink 28 and the inner surface of the bottom wall 7 of the case 5.

As shown in FIG. 11, another sixth sealing member 76 is likewise disposed between the heat sink 28 and the top wall 6 of the case 5. This sixth sealing member 76 is compressed by the heat sink 28 and the inner surface of the top wall 6 of the case 5 and thereby seals the space between them airtight.

As shown in FIG. 11, the keyboard mounting portion 17 of the embodiment has a relatively large opening and the keyboard 9 is thereby exposed to the inside space of the case 5. The upper sixth sealing member 76 extends to between the heat sink 28 and the bottom surface of a left end portion of the keyboard 9. This sixth sealing member 76 is compressed by the heat sink 28 and the bottom surface of the keyboard 9 and thereby seals the space between them airtight.

On the other hand, as shown in FIG. 10, a seventh sealing member 77 is disposed between the second surface 31b of the circuit board 31 and the inner surface of the top wall 6 of the case 5. The seventh sealing member 77 is compressed by the circuit board 31 and the inner surface of the top wall 6 of the case 5 and thereby seals the space between them airtight. Where board components are mounted on the second surface 31b of the circuit board 31, a sealing member disposed between any of those board components and the inner surface of the top wall 6 of the case 5 is also a “sealing member disposed between the second surface of the circuit board and the inner surface of the case.”

As shown in FIG. 10, the seventh sealing member 77 extends to between the second surface 31b of the circuit board 31 and a left end portion of the keyboard 9. The seventh sealing member 77 is compressed by the second surface 31b of the circuit board 31 and the inner surface of the left end portion of the keyboard 9 and seals the space between them airtight.

For example, the seventh sealing member 77 has approximately the same shape as the third sealing member 73 and the fourth sealing members 74 integrated. The shape of the seventh sealing member 77 is not limited to such a shape.

The seventh sealing member 77 cooperates with the top wall 6 of the case 5 (or the keyboard 9) and the left side wall 8c of the case 5 to form the second flow passage 91b of the wind guide passage 91 through which a cool wind flows from the cooling fan 24 toward the heat sink 28. That is, the seventh sealing member 77 serves as a partial wall of the wind guide passage 91. As shown in FIG. 9, the power circuit components 49 are located in the second flow passage 91b.

Air which is discharged from the first portion 24ca of the air discharge outlet 24c of the cooling fan 24 flows through the first flow passage 91a and reaches the first portion 28a of the heat sink 28. Air which is discharged from the second portion 24cb of the air discharge outlet 24c of the cooling fan 24 flows through the second flow passage 91b and reaches the second portion 28b of the heat sink 28. The interval between the second surface 31b of the circuit board 31 and the top wall 6 of the case 5 is shorter than that between the first surface 31a of the circuit board 31 and the bottom wall 7 of the case 5.

As shown in FIG. 8, the second room 62 is formed in a left end portion of the case 5 in such a manner as to be enclosed by the memory slot connector 44, the third sealing member 73, the first power coil 47, the fourth sealing member 74, the LCD connector 45, the boss 95, the rib 96, the seventh sealing member 77, and the left side wall 8c of the case 5. The related components of the embodiment do not separate the second room 62 in the case 5 completely but partially. Alternatively, the second room 62 may be separated completely in the case 5.

The first air outlets 26 and the second air outlets 27 of the case 5, the CPU 41, the power circuit components 43, the power circuit components 49, the heat sink 28, the heat pipe 34, the radiator plate 35, and the air discharge outlet 24c of the cooling fan communicate with or are exposed in the second room 62.

As shown in FIG. 4, the case 5 has the third room 63 which is separated from the first room 61 and the second room 62 at least partially. The third room 63 is separated from the first room 61 and the second room 62 by the second sealing member 72, the boss 95, the rib 96, the memory slot connector 44, the third sealing member 73, the first power coil 47, the fourth sealing member 74, the LCD connector 45, and the seventh sealing member 77.

As shown in FIG. 2, the third room 63 communicates with the outside via vent holes 98 which are formed through the bottom wall 7 of the case 5. As shown in FIG. 4, the PCH 42, the memory 81, the ODD 32, and the storage device 33 are exposed in the third room 63. No heat radiation member is attached to the PCH 42 and the memory 81 and they radiate heat naturally.

The first portion 31c of the circuit board 31 is exposed in the second room 62, and the second portion 31d of the circuit board 31 is exposed in the third room 63. The related components of the embodiment do not separate the third room 63 in the case 5 completely but partially. Alternatively, the third room 63 may be separately completely in the case 5.

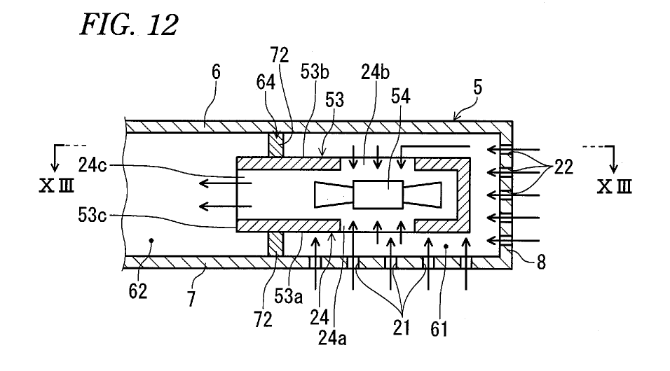

Next, the workings of the electronic apparatus 1 will be described with reference to FIGS. 12 to 14 which show its wind shield structure schematically.

As shown in FIGS. 12 and 13, a space of the case 5 is divided into the first room 61 and the second room 62. The structure (first sealing members 71 and second sealing members 72) for obstructing air flow is provided between the first room 61 and the second room 62. The first air suction inlets 24a and the second air suction inlet 24b of the cooling fan 24 communicate with the first room 61. The air discharge outlet 24c of the cooling fan 24 communicates with the second room 62. In this manner, a partially sealed space in which the air suction inlets 24a and 24b of the cooling fan 24 are confined is formed in the front-left corner portion of the case 5.

The cooling fan 24 sucks air from outside the case 5 into the first room 61 and discharges the air from the first room 61 to the second room 62. The air suction inlets 24a and 24b of the cooling fan 24 do not communicate with the second room 62 or the third room 63. Therefore, the cooling fan 24 sucks no or only a little air that has been heated by the CPU 41, the PCH 42, the power circuit components 43, or any of the other heat generation bodies located in the second room 62 or the third room 63.

The cooling fan 24 sucks low-temperature air from outside the case 5 through the first room 61 and discharges the low-temperature air to the second room 62, that is, toward the CPU 41 etc. Although in the embodiment the air inlets are formed in the top wall 6, the bottom wall 7, and the circumferential wall 8 of the case 5, it suffices that the air inlets be formed in at least one of the top wall 6, the bottom wall 7, and the circumferential wall 8 of the case 5.

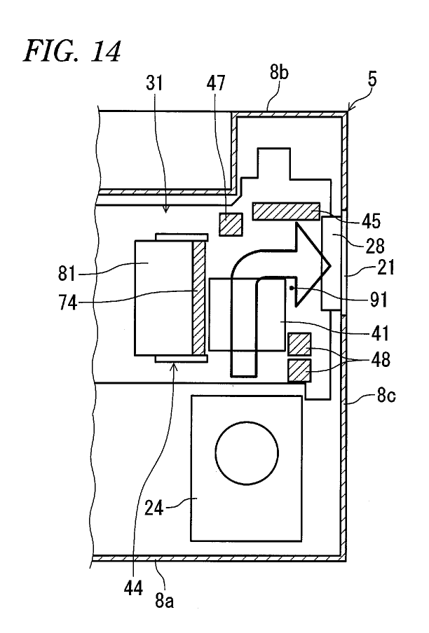

As shown in FIG. 14, the wind guide passage 91 for guiding a cool wind from the cooling fan 24 toward the heat sink 28 is formed in the case 5 by the board components which are mounted on the circuit board 31. More specifically, walls of the wind guide passage 91 are formed on both sides by the memory slot connector 44, the first power coil 47, the LCD connector 45, and the second power coil 48.

That is, the spaces enclosed by the memory slot connector 44, the first power coil 47, the LCD connector 45, the second power coil 48, the circuit board 31, and the bottom wall 7 and the top wall (or the keyboard 9) of the case 5 constitute the wind guide passage 91. Furthermore, in the embodiment, the third to seventh sealing members 73-77 enhance the airtightness of the wind guide passage 91.

With the above structure, a cool wind that is discharged from the cooling fan 24 flows toward the heat sink 28 through the space that is located under the circuit board 31 as indicated by an arrow in FIG. 14. That is, a cool wind that is discharged from the cooling fan 24 flows in a concentrated manner (i.e., without spreading widely in the case 5) and hits the CPU 41, the heat sink 28, etc. reliably, and thereby cools the CPU 41, the heat sink 28, etc. efficiently.

The above-described structure can increase the cooling efficiency.

Assume an air suction structure in which air suction inlets that are formed in the bottom wall of a cooling fan face air inlets of the bottom wall of a case and an air suction inlet that is formed in the top wall of the cooling fan communicates with the inside of the case. In this case, whereas air suction inlets formed in the bottom wall of the cooling fan can take in low-temperature fresh air, the air suction inlet formed in the top wall of the cooling fan sucks air that exists inside the case. Therefore, air that is discharged from the cooling fan has a temperature that is increased to some extent and cannot efficiently cool the heat sink 28 etc. that are exposed to that air.

In contrast, with the structure according to the embodiment, the wind shields 64 which partition the inside space of the case at least partially are provided between the air discharge outlet 24c and the air suction inlets 24a and 24b of the cooling fan 24. As a result, air that is discharged from the air discharge outlet 24c and then heated by the CPU 41 and the heat sink 28 is hardly sucked again through the air suction inlets 24a and 24b. Therefore, air having a relatively low temperature can be sent to the CPU 41 and the heat sink 28 and hence the heat radiation efficiency can be increased.

In the embodiment, the wind shields 64 which separate, in the case 5, at least partially, the first room 61 which communicates with the air inlets 21, 22, and 23 of the case 5 and the air suction inlets 24a and 24b of the cooling fan 24 from the second room 62 with or in which the air outlets 26 and 27 of the case 5, the CPU 41, the heat sink 28, the heat pipe 34, and the air discharge outlet 24c of the cooling fan 24 communicate or are exposed. As a result, air that has been heated by the CPU 41, the heat sink 28, and the heat pipe 34 hardly returns to the air suction inlets 24a and 24b of the cooling fan 24.

In particular, in the embodiment, the first room 61 is provided which takes ambient air into the case 5 and the first air suction inlets 24a formed in the bottom wall 53a of the cooling fan 24 and the air suction inlet 24b formed in the top wall 53b of the cooling fan 24 both communicate with the first room 61. On the other hand, such heat generation bodies as the CPU 41 are housed in the second room 62 which is separated from the first room 61. By virtue of this structure, in addition to the first air suction inlets 24a formed in the bottom wall 53a of the cooling fan 24, the air suction inlet 24b formed in the top wall 53b of the cooling fan 24 can suck low-temperature fresh air rather than heated air that exists inside the case 5.

Therefore, lower-temperature air can be sent to the CPU 41 and the heat sink 28 to increase the heat radiation efficiency further. In other words, the structure is provided which allows the cooling fan 24 incorporated in the case 5 to suck air as high a percentage as possible (as close to 100% as possible) of which is fresh air and to discharge (send) air to the inside of the case 5 100%, irrespective of the kind of the cooling fan 24.

The cooling fan 24 is relatively large in height among the components housed in the case 5. And the cooling fan 24 is disposed in the space under the palm rest 18 which is thicker than the space under the keyboard mounting portion 17, which makes it possible to reduce the thickness of the case 5.

Again assume the air suction structure in which air suction inlets that are formed in the bottom wall of a cooling fan face air inlets of the bottom wall of a case and an air suction inlet that is formed in the top wall of the cooling fan communicates with the inside of the case. In this case, if the air inlets of the bottom wall of the case are closed for a certain reason, the air suction inlets formed in the bottom wall of the cooling fan suck air that has been heated inside the case to possibly lower the cooling efficiency.

In contrast, in the embodiment, the case 5 is provided with the first room 61 for suction and the first room 61 has the second air inlets 22 in addition to the first air inlets 21. With this structure, even if the first air inlets 21 are closed, the first room 61 still communicates with the outside via the second air inlets 22. Since the air suction inlets 24a and 24b of the cooling fan 24 communicate with the first room 61, they can suck low-temperature air via the first room 61. Therefore, the cooling efficiency is not prone to decrease even if a part of the air inlets of the case 5 is closed.

In particular, since the first air inlets 21 are formed in the bottom wall 7 of the case 5 and the second air inlets 22 are formed in the circumferential wall 8 of the case 5, the probability that these two sets of air inlets 21 and 22 are both closed is low, that is, the first room 61 can communicate with the outside at a very high probability.

Even in the case where a second heat generation body (e.g., PCH 42) which works well with natural heat radiation is disposed in the third room 63, since the wind shields 64 separate the third room 63 from the first room 61 and the second room 62 at least partially in the case 5, a cool wind that is discharged from the cooling fan 24 can be sent to the second room 62 in a concentrated manner and air that has been heated in the third room 63 is hardly sucked by the cooling fan 24. The cooling efficiency of the whole apparatus 1 can thus be increased.

### Second Embodiment

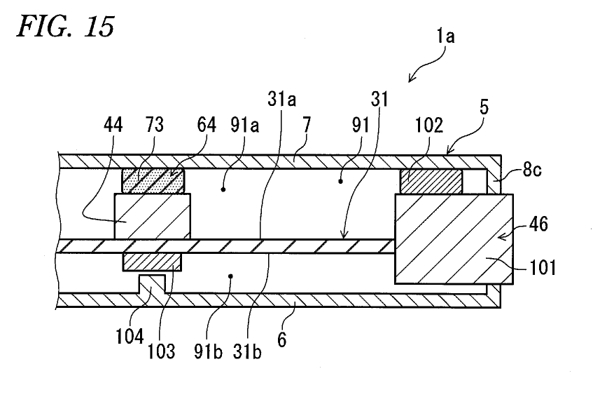

Next, an electronic apparatus 1a according to a second embodiment of the invention will be described with reference to FIG. 15. Members etc. having the same or similar functions as corresponding ones in the first embodiment will be given the same reference symbols as the latter and will not be described in detail. Members etc. that will not be described below are the same as corresponding ones in the first embodiment.

As shown in FIG. 15, in this embodiment, the I/O connector 46 serves as a partial wall of the wind guide passage 91. The I/O connector 46 has a metal shell 101 and a terminal portion which is provided inside the shell 101. The case 5 is made of a metal. Alternatively, the case 5 may be composed of a resin body and a conductive layer formed on its inside surfaces. The conductor layer is formed by plating, coating of a conductor layer, sticking of metal foil, or the like.

A conductive member 102 is sandwiched between the I/O connector 46 and the bottom wall 7 of the case 5. The conductive member 102 is a gasket. Alternatively, it may be a leaf spring or the like. Sandwiched between the I/O connector 46 and the bottom wall 7 of the case 5, the conductive member 102 electrically connects the I/O connector 46 to the case 5. The conductive member 102 thus functions as an electrostatic discharge (ESD) member or an electromagnetic interference (EMI) member.

In the embodiment, the conductive member 102 serves as a partial wall of the wind guide passage. The connector for which the conductive member 102 is provided is not limited to the I/O connector 46 and may be another kind of connector.

As shown in FIG. 15, a heat generation component 103 is mounted on the second surface 31b of the circuit board 31. The heat generation component 103 is a power coil, a capacitor, an IC, or the like. The heat generation component 103 may be another component whose temperature becomes higher than an average temperature of the circuit board 31 while it is in operation. In the embodiment, the heat generation component 103 serves as a partial wall of the wind guide passage 91.

The case 5 has a rib 104 (example wind shield) whose projection length is adjusted according to the height of the associated component (in the embodiment, the heat generation component 103) that serves as a partial wall of the wind guide passage 91. The rib 104 projects from the inner surface of the top wall 6 of the case 5 toward the associated component that serves as a partial wall of the wind guide passage 91 so that a gap of several millimeters, for example, is formed between them. The rib 104 also serves as a partial wall of the wind guide passage 91.

The above-described structure can increase the cooling efficiency in the same manner as in the first embodiment.

### Third Embodiment

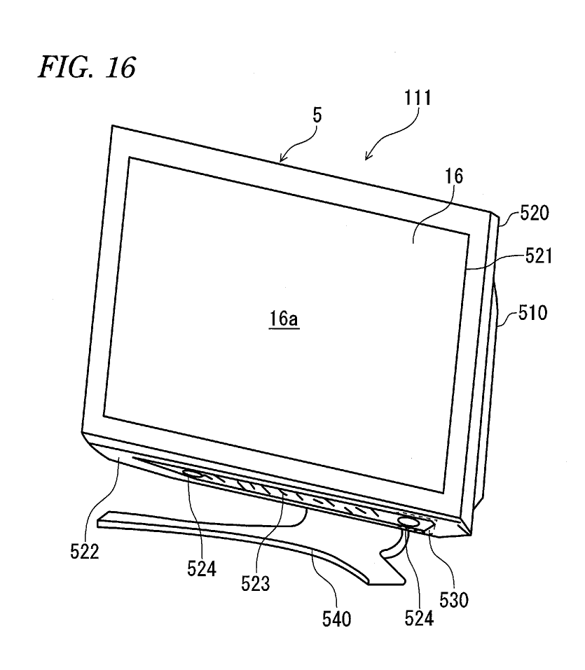

Next, a display apparatus 111 according to a third embodiment of the invention will be described with reference to FIGS. 16-18. Members etc. having the same or similar functions as corresponding ones in the first embodiment will be given the same reference symbols as the latter and will not be described in detail. Members etc. that will not be described below are the same as corresponding ones in the first embodiment.

As shown in FIGS. 16 to 18, the display apparatus 111 is equipped with a case 5 and a display panel 16 which is housed in the case 5. The display apparatus 111 is an all-in-one personal computer, for example. A structure that is similar to the one according to the first or second embodiment is provided inside the case 5.

As shown in FIGS. 16 to 18, the case 5 of the display apparatus 111 has a cover portion 510 which is formed with air outlets 511 and first air inlets 512 and a mask portion 520 which is connected to the cover portion 510 with a display panel 16 sandwiched in between and which is formed or provided with an opening 521 through which the display panel 16 is exposed and a slant portion 522 which extends to the cover portion 522. The slant portion 522 is formed or provided with second air inlets 523 and a sound emitting portion 524. This structure makes it possible to suck from both sides of the case 5 (the user side and the side opposite to it) and thereby increases the cooling efficiency. The slant portion 522, which is a bottom portion of the case 5, extends to the cover portion 510 so that the mask portion 520 expands in the vertical direction. This structure can cause the user to feel as if the case 5 were smaller than its actual size. Although in this embodiment the slant portion 522 is integral with the mask portion 520, the invention is not limited to such a case. The slant portion 522 may be a separate member which is attached to the mask portion 520 and the cover portion 510.

As shown in FIGS. 16-18, speakers 530 are provided between the slant portion 522 and the cover portion 510. Sound output portions 531 of the speakers 530 are opposed to the sound emitting portion 524. This structure makes it possible to secure necessary capacities of the speakers 530 and to direct the sound output directions of the speakers 530 toward the user side.

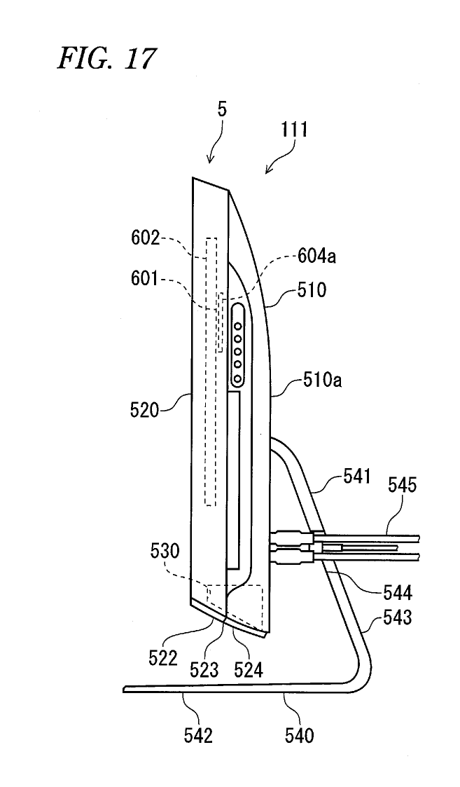

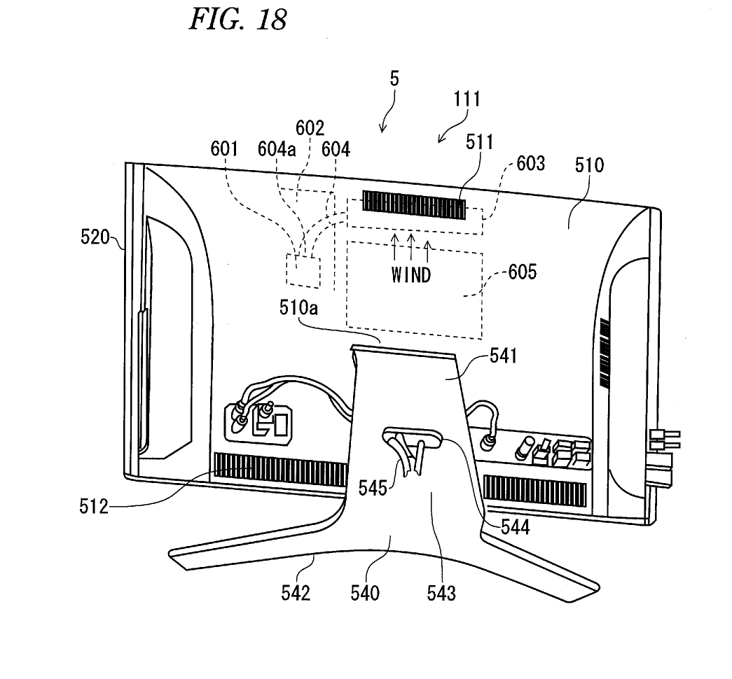

As shown in FIGS. 17 and 18, the case 5 is supported by a support stand 540. The support stand 540 has an end portion 541 which is connected to a member that is located inside a central portion 510a of the cover portion 510, legs 542 to be placed on, for example, the top plate of a desk, and a middle portion 543 which connects the end portion 541 and the legs 542. The middle portion 543 is formed with an opening 543 which extends in the longitudinal direction of the display apparatus 111. The opening 544 is formed at approximately the same height as plural cables 545 to be connected to the display apparatus 111 on the side of the cover portion 510. This structure makes it possible to insert the cables 545 through the opening 544 and thereby makes the backside cables 545 less conspicuous when the display apparatus 111 is seen from the front side.

As shown in FIG. 18, a circuit board 602 which is mounted with a heat generation body 601, a heat sink 603 which faces the air outlets 511, a heat pipe 604 which thermally connects the heat generation body 601 and the heat sink 603, and a fan 605 whose air discharge outlet is directed to the heat sink 603.

The heat sink 603 is located above the heat generation body 601. The heat pipe 604 has, at the bottom, a heat receiving portion 604a for receiving heat from the heat generation body 601. This structure can prevent a top heat phenomenon and keep the cooling efficiency high.

Like the electronic apparatus 1 and 1a according to the first and second embodiments, the display apparatus 111 having the above configuration can increase the cooling efficiency.

Although the electronic apparatus 1 and 1a and the display apparatus 111 according to the first, second, and third embodiments of the invention have been described above, the invention is not limited to the embodiments themselves. In the practice stage, the invention can be embodied in such a manner that constituent elements of each embodiment are modified without departing from the spirit and scope of the invention.

For example, the third room 63 need not always be separated in the case 5. It suffices that the first room 61 and the second room 62 be separated. The wind guide passage 91 need not always be formed. That is, the sealing members 73 to 77 may be omitted. The first room 61, the second room 62, and the third room 63 may be separated by members other than sealing members, such as portions (e.g., ribs) of the case 5. The first air suction inlets 24a need not always be opposed to the air inlets 21 of the bottom wall 7.

While certain embodiment has been described, the exemplary embodiment has been presented by way of example only, and is not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A display apparatus comprising:
a display panel;
a case including:
a cover portion provided with an air outlet and a first air inlet;
a mask portion provided with an opening which is connected to the cover portion via the display panel and through which the display panel is exposed, a slant portion which extends to the cover portion, and a second air inlet located at the slant portion,
wherein the apparatus further comprising:
a support stand configured to support the case;
a circuit board housed in the case and mounted with a heat generation body;
a heat sink housed in the case and configured to face the air outlet;
a heat pipe configured to thermally connect the heat generation body and the heat sink; and
a fan including an air discharge outlet which is directed to the heat sink.

2. The apparatus of claim 1, wherein the slant portion is located, on a side of the support stand, in a region of the mask portion.

3. The apparatus of claim 2, wherein the heat sink is disposed above the heat generation body.

4. The apparatus of claim 3, wherein the heat pipe includes, as a bottom portion, a heat receiving portion for receiving heat from the heat generation body.

5. The apparatus of claim 2, wherein the slant portion is located below the first air inlet.

6. The apparatus of claim 2 further comprising:
speakers which are provided between the slant portion and the cover portion,
wherein the slant portion is provided with a sound emitting portion for emitting a sound produced by the speakers.

7. An electronic apparatus comprising:
a case including a first wall which is provided with an input unit for receiving an input operation and a second wall which is opposed to the first wall;
a circuit board housed in the case and mounted with a heat generation body;
a heat sink housed in the case;
a heat pipe configured to thermally connect the heat generation body and the heat sink; and
a fan including an air discharge outlet which is directed to the heat sink,
wherein the first wall includes a slant portion which extends toward the second wall and is provided with a first air inlet, and the second wall includes a second air inlet.

8. The apparatus of claim 7 further comprising:
a display unit including a display screen; and
a hinge configured to connect the display unit and the case,
wherein the slant portion is located at a first end of the case, the first end being opposite to a second end of the case to which the hinge is connected.

9. The apparatus of claim 8, wherein the fan is provided with an air suction inlet which faces the second air inlet and another air suction inlet which faces a palm rest of the first wall.

10. An electronic apparatus comprising:
a case including:
a first wall which is provided with an input unit for receiving an input operation and a first air inlet; and
a second wall which is opposed to the first wall and provided with a second air inlet and an air outlet; and
a circuit board housed in the case and mounted with a heat generation body.
